(19) United States
(12) Patent Application Publication
(10) Pub. No.: US 2007/0223559 A1
(43) Pub. Date: Sep. 27, 2007

(54) INTELLIGENT KEYBOARD

(75) Inventors: Shih-Fang Wong, Shenzhen (CN); Zhi-Yuan Ye, Shenzhen (CN)

Correspondence Address: NORTH AMERICA INTELLECTUAL PROPERTY CORPORATION, P.O. BOX 506, MERRIFIELD, VA, 22116, US

(73) Assignee: HON HAI PRECISION INDUSTRY CO., LTD., Taipei Hsien (TW)

(21) Appl. No.: 11/627,362

(22) Filed: Jan. 25, 2007

(30) Foreign Application Priority Data
Mar. 3, 2006 (CN) 200610034162.2

(51) Int. Cl. G01K 1/00; H03M 11/00

(52) U.S. Cl. 374/100; 341/22

(57) ABSTRACT

The present invention provides an intelligent keyboard can detect physical signals of environment condition in the intelligent keyboard automatically. The intelligent keyboard includes a microprocessor module, a physical condition detector, a physical condition adjustor, an analog-to-digital converter (AD converter), a memory, and an operation input unit. The physical condition detector samples physical signals of environment condition in the intelligent keyboard. The AD converter converts the physical signals into digitalized environment values. The memory stores reference physical values representing modest ranges of the environment condition. The physical condition adjustor adjusts the environment condition. The microprocessor module comprises an environment controller for processing the environment values inputted from the AD converter and outputting controller commands to control operation of the physical condition adjustor.

### BACKGROUND

1. Technical Field

The present invention relates to a keyboard, particularly to a keyboard with a function of adjusting its physical signals of environment condition therein.

2. Related Art

Because of bad exterior environments, an ordinary keyboard can not supply a modest operation environment for a user. For example, an operating hand is prone to shivers in chilly winter or sweats and becomes moist in hot summer.

The China patent CN98250389, entitled “a warmer signal input device”, issued on Feb. 2, 2000, discloses such a warmer keyboard for a user in cold environment.

However the present keyboard has two disadvantages, firstly, the keyboard adopts a manual switch to adjust the physical condition; a user has to turn on or turn off the switch manually. Secondly, the keyboard adopts an air heater to warm up the keyboard. The air heater is not cute and tiny enough to place near the keyboard. Thirdly, the air heater can just change temperature condition of the keyboard.

Accordingly, it would be advantageous to provide an intelligent keyboard can detect and adjust the physical signals of environment condition automatically. Furthermore, the intelligent keyboard is cute and exquisite enough to place on a desktop. In addition, the intelligent keyboard can detect and adjust not only the temperature signal, but also the moistness signal to a modest one automatically.

### SUMMARY

In view of the foregoing disadvantages inherent in the known keyboard now present in the prior art, the present invention provides an intelligent keyboard make up the shortcomings of present keyboard.

To attain this, the present invention generally includes: a physical condition detector for sampling physical signals of environment condition in the intelligent keyboard; an analog-to-digital converter (AD converter) for converting the physical signals into digitalized environment values; a memory for storing reference physical values representing modest ranges of the environment condition; a physical condition adjustor for adjusting the physical signals of the environment condition; and a microprocessor module comprising an environment controller for processing the environment values inputted from the AD converter and outputting controller commands to the physical condition adjustor.

One object of the present invention is to provide an intelligent keyboard which detects physical signals of environment condition in the intelligent keyboard automatically.

The other object of the present invention is to provide an intelligent keyboard which can adjust the physical condition to a modest range meeting a comfortable and intelligent life.

### BRIEF DESCRIPTION OF THE DRAWINGS

FIG. 1 is a block diagram of an intelligent keyboard in accordance with a preferred embodiment of the present invention; and

FIG. 2 describes a flow chart of a preferred procedure for presenting an operation process according to the present invention.

### DETAILED DESCRIPTION OF THE EMBODIMENTS

The present invention provides an intelligent keyboard 1 which samples and adjusts physical signals of environment condition in the intelligent keyboard 1 automatically.

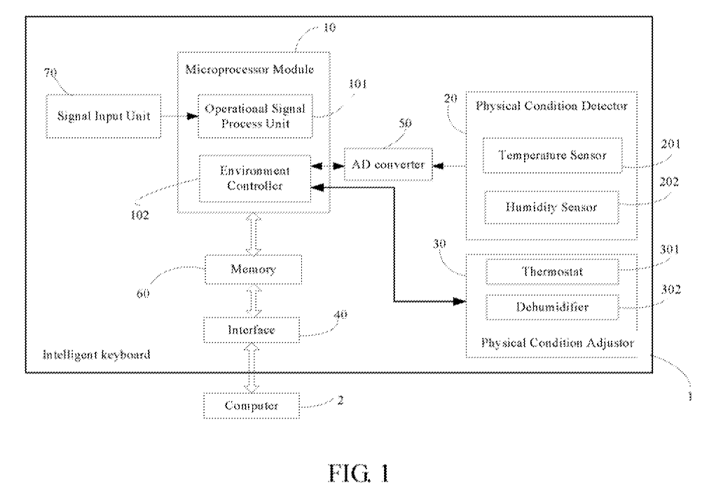

Shown in FIG. 1 is a block diagram of the intelligent keyboard 1 in accordance with a preferred embodiment of the present invention. The intelligent keyboard 1 obtains power supply from a computer 2 and exchanges data with the computer 2 through an interface 40. The interface 40 is a USB (universal serial bus) port or a PS/2 port.

The intelligent keyboard 1 includes a microprocessor module 10, a physical condition detector 20, a physical condition adjustor 30, an analog-to-digital converter (AD converter) 50, a memory 60, and an operation input unit 70. The physical condition detector 20 is configured for sampling physical signals of environment condition in the intelligent keyboard. The AD converter 50 is configured for converting the physical signals into digitalized environment values. The memory 60 is configured for storing reference physical values representing modest ranges of corresponding to different environment conditions. The physical condition adjustor 30 is configured for adjusting the environment condition of the intelligent keyboard. The microprocessor module 10 comprises an environment controller 102 for processing the digitalized environment values inputted from the AD converter 50 and outputting controller commands to the physical condition adjustor 30.

The operation input unit 70 generates operational signals in correspondence to manual operations performed on the intelligent keyboard 1. The operation input unit 70 includes all kinds of keys and buttons in the keyboard 1. The microprocessor module 10 comprises an operational signal process unit 101 for processing the operational signals generated by the operation input unit 70.

The physical condition detector 20 includes a temperature sensor 201 and a humidity sensor 202. The temperature sensor 201 is configured for sampling a temperature signal in the intelligent keyboard 1. The humidity sensors 202 are configured for sampling a moistness signal in the intelligent keyboard 1. The temperature sensors 201 and the humidity sensors 202 are configured at appropriate positions of the intelligent keyboard 1. The appropriate positions are where the sensors can efficiently detect changes of the physical condition, such as an enter key, ctrl key and some other letter keys frequently used.

The temperature signal sampled by the temperature sensor 201 and the moistness signal sampled by the humidity sensor 202 are inputted to the AD converter 50. The AD converter 50 converts the temperature signal into a digitalized temperature value and converts the moistness signal into a digitalized dampness value.

The reference physical values stored in the memory 60 include a critically high temperature value, a critically low temperature value, and a critically wet value. The critically high temperature value and the critically low temperature value define a range of modest temperature. The critically wet value defines a critical wetness and a suitable moistness. The environment controller 102 is configured for processing the environment values (i.e., the temperature value and the dampness value).

The physical condition adjustor 30 includes a thermostat 301 and a dehumidifier 302. The thermostat 301 is configured for adjusting temperature of the intelligent keyboard 1. The dehumidifier 302 is configured for adjusting moistness of the intelligent keyboard 1. The thermostat 30 and the dehumidifier 302 may be a micro-fan, a heater, or a combination of them.

The environment controller 102 compares the temperature value with the critically high temperature value and the critically low temperature value. If the temperature value is between the critically high temperature value and the critically low temperature value, the environment controller 102 disables the thermostat 301. If the temperature value is higher than the critically high temperature value or lower than the critically low temperature value, the environment controller 102 enables the thermostat 301. In the preferred embodiment, if the temperature value is higher than the critically high temperature value, the thermostat 301 adopts the micro-fan to cool down the intelligent keyboard 1, so as to decrease the temperature of the intelligent keyboard 1. If the temperature value is lower than the critically low temperature value, the thermostat 301 adopts the heater to warm up the intelligent keyboard 1 so as to increase the temperature of the intelligent keyboard 1.

The environment controller 102 compares the dampness value with the critically wet value. If the dampness value is higher than the critically wet value, the environment controller 102 enables the dehumidifier 302. In the preferred embodiment, if the dampness value is higher than the critically wet value, the dehumidifier 302 enables the micro-fan to dehumidify the intelligent keyboard 1, so as to decrease the humidity of the intelligent keyboard 1. If the dampness value is higher than the critically wet value, and if the temperature value is lower than the critically high temperature value, the dehumidifier 302 further enables the heater to dehumidify the intelligent keyboard 1. If the dampness value is lower than the critically wet value, and if the temperature value is between the critically high temperature value and critically low temperature value, the environment controller 102 disables the dehumidifier 302 to stop the micro-fan or the heater.

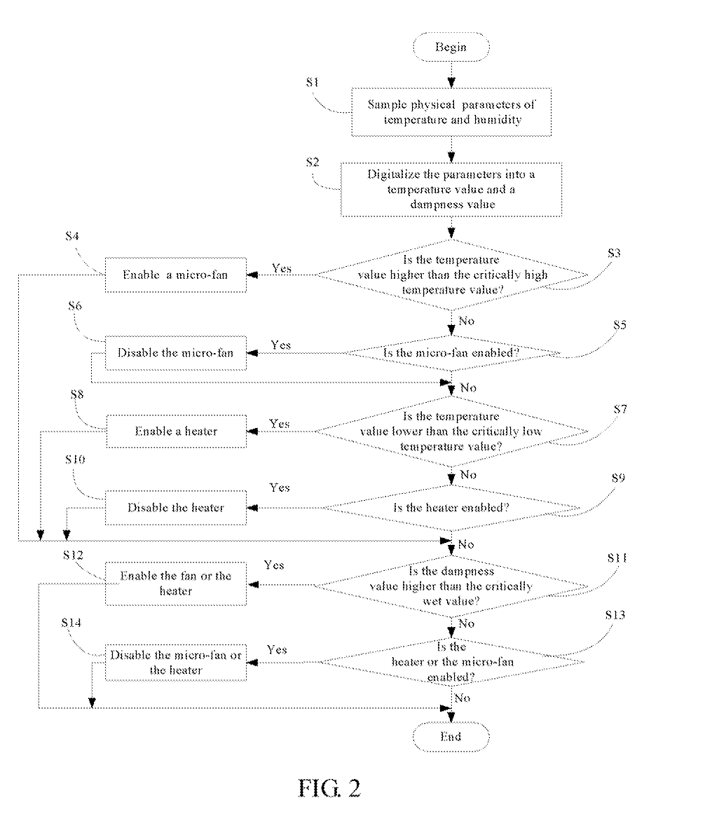

FIG. 2 is a flow chart illustrating a preferred procedure for adjusting the physical condition in the intelligent keyboard 1.

In step S1, after being powered on, the temperature sensors 201 and the humidity sensors 202 is signaled to sample the temperature and the humidity in the intelligent keyboard 1 respectively, thus to obtain the temperature signal and the moistness signal. In step S2, the AD converter 50 converts the temperature signal into the digitalized temperature value and converts the moistness signal into the digitalized dampness value respectively.

In step S3, the environment controller 102 compares the temperature value with the critically high temperature value stored in the memory 60. If the temperature value is higher than the critically high temperature value, in step S4, the environment controller 102 enables the micro-fan to cool down the temperature in the intelligent keyboard 1, and the procedure goes to step S11. If the temperature value is lower than the critically high temperature value, in step S5, the environment controller 102 detects whether the micro-fan is enabled. If the micro-fan is disabled, the procedure goes to step S7 directly. If the micro-fan is enabled, in step S6, the environment controller 102 disables the micro-fan, and the procedure goes to step S7.

In the step S7, the environment controller 102 compares the temperature value with the critically low temperature value stored in the memory 60. If the temperature value is lower than the critically low temperature value, in step S8, the environment controller 102 enables the heater to warm up the temperature in the intelligent keyboard 1, and the procedure goes to step S11. If the temperature value is higher than the critically low temperature value, in step S9, the environment controller 102 detects whether the heater is enabled. If the heater is disabled, the procedure goes to step S11 directly. If the heater is enabled, in step S10, the environment controller 102 disables the heater, and the procedure goes to step S11.

In step S11, the environment controller 102 compares the dampness value with the critically wet value stored in the memory 60. If the dampness value is higher than the critically wet value, in step S12, the environment controller 102 enables the micro-fan or the heater to dehumidify the intelligent keyboard 1, and the procedure is finished. If the dampness value is lower than the critically wet value, in step S13, the environment controller 102 detects whether the micro-fan or the heater is enabled. If the micro-fan or the heater is disabled, the procedure is finished. If the micro-fan or the heater is enabled, in step S14, the environment controller 102 disables the micro-fan or the heater, and the procedure is finished.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. An intelligent keyboard comprising:
a physical condition detector for sampling physical signals of environment condition in the intelligent keyboard;
an analog-to-digital converter (AD converter) for converting the physical signals into digitalized environment values;
a memory for storing reference physical values representing modest ranges of corresponding to different environment conditions;
a physical condition adjustor for adjusting the environment condition of the intelligent keyboard; and
a microprocessor module comprising an environment controller for processing the digitalized environment values inputted from the AD converter and outputting controller commands to the physical condition adjustor.

2. The intelligent keyboard according to claim 1, further comprising an operation input unit for generating operational signals in correspondence to manual operations performed on the intelligent keyboard, and wherein the microprocessor module comprises an operational signal process unit for processing the operation signals generated by the operating input unit.

3. The intelligent keyboard according to claim 1, further comprising an interface connected to a computer for obtaining power supply from the computer and exchanging data with the computer.

4. The intelligent keyboard according to claim 1, wherein the physical condition detector comprises a temperature sensor for sampling a temperature signal in the intelligent keyboard, and a humidity sensors for sampling a moistness signal in the intelligent keyboard.

5. The intelligent keyboard according to claim 4, wherein the physical condition detector is configured at an appropriate position of the intelligent keyboard where is available to detect changes of the environment.

6. The intelligent keyboard according to claim 5, wherein the AD converter converts the temperature signal into a digitalized temperature value and converts the moistness signal into a digitalized dampness value.

7. The intelligent keyboard according to claim 6, wherein the reference physical values comprise a critically high temperature value, a critically low temperature value, and a critically wet value.

8. The intelligent keyboard according to claim 7, wherein the physical condition adjustor comprises a thermostat for adjusting temperature of the intellectual keyboard, and a dehumidifier for adjusting moistness of the intellectual keyboard.

9. The intelligent keyboard according to claim 8, wherein the environment controller compares the temperature value with the critically high temperature value and the critically low temperature value, and outputs a temperature command to the thermostat; and the thermostat adjusts the temperature in the intelligent keyboard according to the temperature command.

10. The intelligent keyboard according to claim 9, wherein the environment controller enables the thermostat if the temperature value is higher than the critically high temperature value or lower than the critically low temperature value; otherwise disables the thermostat if the temperature value is between the critically high temperature value and the critically low temperature value.

11. The intelligent keyboard according to claim 10, wherein the thermostat comprises a micro-fan and a heater.

12. The intelligent keyboard according to claim 1, wherein the environment controller enables the micro-fan if the temperature value is higher than the critically high temperature value, and disables the micro-fan if the temperature value is lower than the critically low temperature value; and the environment controller enables the heater if the temperature value is lower than the critically high temperature value, and disables the heater if the temperature value is higher than the critically low temperature value.

13. The intelligent keyboard according to claim 8, wherein the environment controller compares the dampness value with the critically wet value, and then outputs a humidity command to the dehumidifier; and the dehumidifier adjusts the moistness of the intelligent keyboard according the humidity command.

14. The intelligent keyboard according to claim 13, wherein the environment controller enables the dehumidifier if the dampness value is higher than the critically wet value; or disables the dehumidifier if the dampness value is lower than the critically wet value.

15. The intelligent keyboard according to claim 14, wherein the dehumidifier comprises a micro-fan and a heater.

16. The intelligent keyboard according to claim 15, wherein
the environment controller enables the micro-fan if the dampness value is higher than the critically wet value and the temperature value is higher than the critically low temperature value;
the environment controller enables the heater if the dampness value is higher than the critically wet value and the temperature value is lower than the critically low temperature value;
the environment controller disables the micro-fan if the dampness value is lower than the critically wet value and the temperature is lower than the critically high temperature value;
the environment controller disables the heater if the dampness value is lower than the critically wet value as well as the temperature is higher than the low temperature value.
